(19) United States
(12) Patent Application Publication
(10) Pub. No.: US 2007/0127731 A1
(43) Pub. Date: Jun. 7, 2007

(54) Selective audio signal enhancement

(75) Inventors: Ronaldus Maria Aarts, Eindhoven (NL); Okke Ouweltjes, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 10/580,674

(22) PCT Filed: Nov. 30, 2004
(86) PCT No.: PCT/IB04/52599

§ 371 Date: May 26, 2006

(30) Foreign Application Priority Data
Dec. 1, 2003 (EP) 03104463.9

(51) Int. Cl. H03G 3/00

(52) U.S. Cl. 381/61; 381/98

(57) ABSTRACT

An audio signal may be enhanced by adding enhancement signals, such as harmonics and/or sub-harmonics of the signal's bass components. To avoid any unwanted enhancement signals during soft passages or speech, it is proposed to monitor the audio signal for tonal signal components in a frequency range and to only add the enhancement signals if such tonal signals are detected. A tonal detector (3) may comprise sine and cosine generators whose frequency is preferably equal to a dominant frequency of the frequency range.

The present invention relates to a method of selective audio signal enhancement. More in particular, the present invention relates to a method of and a device for selectively improving the perceived quality of an audio signal by adding enhancement (improvement) signals.

It is well known to enhance audio signals, for example by amplifying one frequency range more strongly than another frequency range. In this way, it is possible to “boost” higher and lower frequencies which are typically perceived to be less loud than mid-range frequencies. However, it has been found that many transducers are not capable of rendering high and low frequencies at an appreciable sound level without introducing distortion. This is especially a problem for low audio frequencies or “bass” frequencies.

It has been proposed to enhance an audio signal by adding harmonics of the bass signal, as disclosed in, for example, U.S. Pat. No. 6,134,330 and U.S. Pat. No. 6,111,960 (Philips). The enhancement signals are produced by a harmonics generator and then added to the (amplified) original audio signal. The added harmonics are perceived as an amplified bass signal. It has further been proposed to add sub-harmonics of the audio signal to create the impression of bass enhancement, as disclosed in, for example, International Patent Application WO 01/84880 (Philips).

Although the audio signal enhancement methods of the patent documents mentioned above provide a significant improvement, it has been found that they may not always function satisfactorily. That is, during music passages having a low sound level, or during speech the bass enhancement is often not desired. Any enhancement signals produced during such passages are often perceived as a disturbance of the audio signal.

It is therefore an object of the present invention to overcome these and other problems of the Prior Art and to provide a method of and a device for enhancing audio signals in which enhancement signals are selectively applied.

Accordingly, the present invention provides a method of enhancing an audio signal, the method comprising the steps of:

detecting tonal signal components in a frequency range of the audio signal,

producing enhancement signals, and

adjusting the level of the enhancement signals in dependence of any detected tonal signal components in said frequency range.

By detecting tonal signals in the audio signal and adjusting the level of the enhancement signal(s) in dependence of the presence of any tonal signals, it is possible to considerably reduce the sound level of the enhancement signals or even eliminate the enhancement signals when no tonal signals are present.

It is noted that tonal signals are sinusoidal signals, that is signals which can be described as a sine signal and any harmonics of the sine signal. In contrast to this, non-tonal signals cannot be described as a combination of sinusoidal signals. Speech signals, for example, typically consist of tonal signals interspersed with noise-like signals. During the tonal signal periods, enhancement signals are normally desired. However, during the noise-like signal periods, enhancements signals are typically less desired and should be reduced in volume or even completely suppressed.

The enhancement signals are preferably harmonics or sub-harmonics of part of the audio signal. This allows audio signals to be improved in the manner of, for example, U.S. Pat. No. 6,111,960 mentioned above. Advantageously, therefore, the frequency range concerned comprises bass frequencies. The present invention provides a method of selectively enhancing an audio signal, dependent on the type of input signal, that is, tonal or non-tonal (noise-like). It is noted that U.S. Pat. No. 6,111,960 mentioned above discloses an input level detector for detecting the level of the input signal so as to normalize the harmonics signals. However, U.S. Pat. No. 6,111,960 does not distinguish between tonal and non-tonal input signals.

In a preferred embodiment of the present invention, the step of detecting tonal frequency components comprises the sub-steps of:

generating a sine signal and a cosine signal,

multiplying both the sine signal and the cosine signal by the audio signal,

low pass filtering the respective multiplied signals, and

determining the geometric average of the low pass filtered signals so as to produce a detection signal.

In this way, a very effective detection of tonal signals may be achieved.

Preferably, the sine and cosine signals both have a frequency which is substantially equal to a dominant frequency of the frequency range. This allows an even more effective detection of tonal signal components. It is noted that the dominant frequency of a particular frequency range typically is the frequency at which the strongest signal component is present, that is, the frequency at which the frequency spectrum of the audio signal in the particular frequency range is at a maximum. However, other measures of the dominant frequency are possible, such as weighted measures which are well known to those skilled in the art.

The present invention also provides a device for enhancing an audio signal, the device comprising:

detector means for detecting tonal signal components in a frequency range of the audio signal,

enhancement means for producing enhancement signals, and

adjustment means for adjusting the level of the enhancement signals in dependence of any detected tonal signal components in said frequency range.

As in the method of the present invention, it is possible to considerably reduce the sound level of the enhancement signals or even eliminate the enhancement signals when no tonal signals are present.

The enhancement means are preferably arranged for producing harmonics or sub-harmonics of part of the audio signal. Preferably, the frequency range concerned comprises bass frequencies.

In an advantageous embodiment the detector means comprise:

generator means for generating a sine signal and a cosine signal,

multiplication means for multiplying the audio signal by the sine signal and the cosine signal respectively,

filter means for filtering the multiplied sine signal and cosine signal respectively, and

averaging means for determining the geometric average of the filtered signals so as to produce a detector signal.

Advantageously, the device of the present invention may further comprise scaling means for scaling the detector signal. This allows the detector signal to be made compatible with other signals present in the device, such as the output signal of the enhancement means.

In a preferred embodiment, the device further comprises frequency tracking means for tracking the frequency in the frequency range and controlling the generator means. Frequency tracking means allow the dominant frequency in any time interval to be determined, this frequency may then be used by the generator means to generate the sine signal and the cosine signal used for the detection.

The present invention also provides a tonal signal detector suitable for use in a device as defined above or in other devices.

The present invention additionally provides an audio system comprising a device as defined above. Such an audio system could for example be constituted by an audio set (“stereo set”) for home or office use comprising an amplifier, an audio source such as a DVD player and/or a tuner, and transducers such as loudspeakers. The audio system could also be constituted by an announcement system, or an audio control and amplification system for theatres. Alternatively, the audio system of the present invention could be part of a television, computer or multimedia system.

The present invention will further be explained below with reference to exemplary embodiments illustrated in the accompanying drawings, in which:

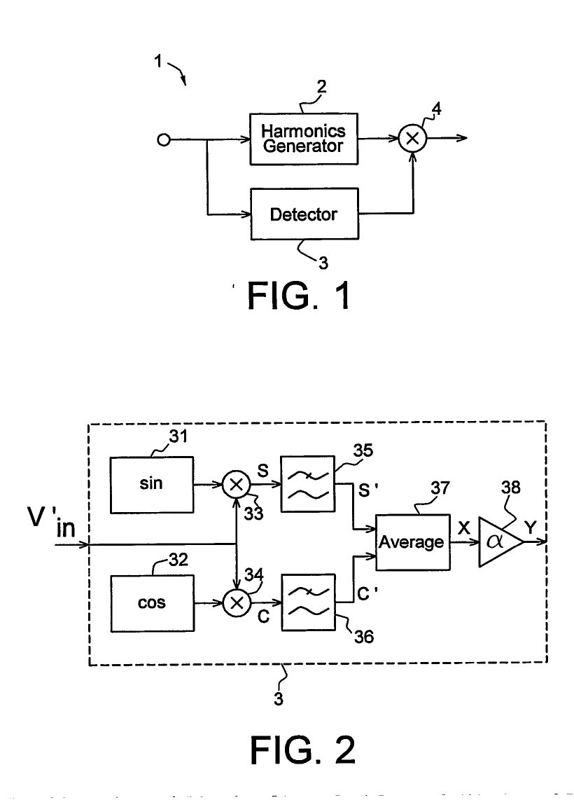

FIG. 1 schematically shows a first embodiment of a device according to the present invention.

FIG. 2 schematically shows a first embodiment of a tonal detector according to the present invention.

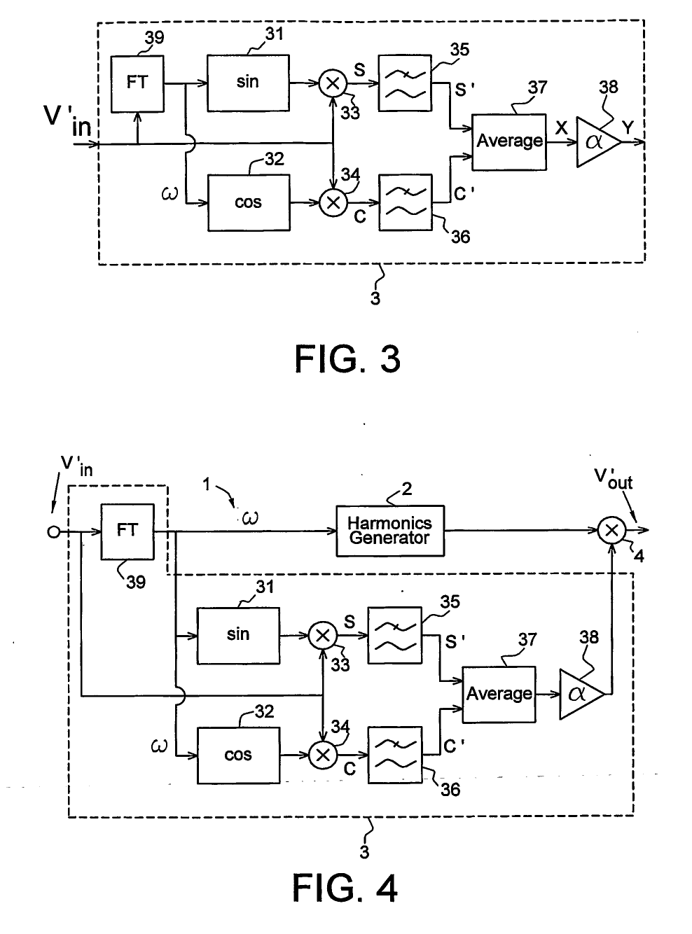

FIG. 3 schematically shows a second embodiment of a tonal detector according to the present invention.

FIG. 4 schematically shows a second embodiment of a device according to the present invention.

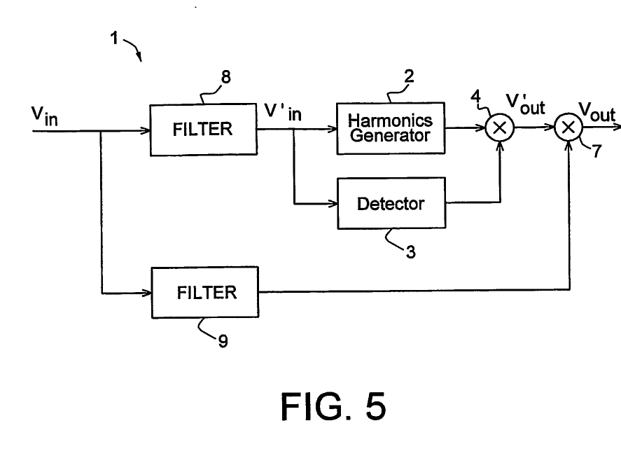

FIG. 5 schematically shows a third embodiment of a device according to the present invention.

The audio signal enhancement device 1 shown merely by way of non-limiting example in FIG. 1 comprises a harmonics generator 2, a detector 3 and a multiplier 4. The harmonics generator 2 serves as an enhancement means and generates enhancement signals, in the example shown harmonics of the input audio signal. The detector 3, which will be further explained with reference to FIGS. 2 and 3, serves to detect tonal audio signals. The multiplier 4 serves to control or adjust the output of the harmonics generator 2, a control signal being supplied by the detector 3.

The device 1 receives an audio signal at its input terminal. This audio signal, which may be limited to a certain frequency band as will be explained later with reference to FIG. 5, is fed to both the harmonics generator 2 and the detector 3. The harmonics generator 2 produces harmonics (or sub-harmonics) of the audio signal and feeds these harmonics to the multiplier 4. The detector 3 detects any tonal signal components in the audio signal and produces a corresponding control signal which is also fed to the multiplier 4. In a preferred embodiment, the control signal produced by the detector 3 is approximately proportional to the amplitude of any tonal signal components, leading to a gradual adjustment of the amplitude of the harmonics signals, but it is also possible for the control signal to be binary, that is, to have two signal values (“on” and “off”) only.

The harmonics signals produced by the harmonics generator 2 are, in the embodiment shown, multiplied by the control signal produced by the detector 3. As a result, the harmonics signals will be passed to the output of the device 1 when tonal signal components are present in the audio signal, and will be substantially suppressed when they are not present. The enhancement (harmonics) signals are therefore selectively output, in dependence of any tonal signal components in the audio signal.

It is noted that the arrangement of FIG. 1 is exemplary only and that various alternative embodiments can be envisaged. For example, the multiplier 4 could be replaced by a controlled switch or a digital logic device containing a look-up table. Alternatively, or additionally, the multiplier 4 or its equivalent could be arranged before instead of after the harmonics generator 2. Instead of the harmonics generator 2 shown, a sub-harmonics generator or any other enhancement signal generator could be utilized.

An embodiment of the detector 3 for detecting tonal signal components is shown in FIG. 2. The audio signal received at the input of the detector 3 is fed to a first multiplier 33 and a second multiplier 34, where it is multiplied by a sine and a cosine signal respectively. The sine signal and the cosine signal are generated in a first generator 31 and a second generator 32 respectively. The frequencies of the sine and the cosine signals are preferably substantially equal and may be predetermined, for example being equal to the middle frequency of a particular frequency band. However, the frequencies of the generators 31 and 32 may also be variable, that is, controlled.

The product of the sine signal and the audio signal is fed to a first low pass filter 35 while its counterpart is fed to a second low pass filter 36. The cut-off frequency of the filters 35 and 36 is in the preferred embodiment approximately equal to the lowest frequency of the frequency range concerned. For example, if the device 1 were to be used for a frequency range of 20-200 Hz, the cut-off frequency of the filters 35 and 36 would preferably be approximately 20 Hz. Low pass filtering the product signal results in the resultant signal becoming frequency-independent. This can be mathematically shown as follows.

Assume that the tonal audio signal V′ᵢₙ can be written as:
V′ᵢₙ=A·sin(ω·t+φ),
where A is the amplitude, ω the (angular) frequency and φ the phase of the signal. Multiplying the signal V′ᵢₙ by a sine and a cosine, both of frequency ω, results in:
S=A·sin(ω·t+φ)·sin(ω·t), and
C=A·sin(ω·t+φ)·cos(ω·t).

The signals S and C can also be written as:
S=½·A·(cos(φ)−cos(2·ω·t+φ)), and
C=½·A·(sin(φ)+sin(2·ω·t+φ)).

Low-pass filtering (filters 35 and 36) removes the signal components having a frequency 2·ω, resulting in:
S′=½·A·cos(φ), and
C′=½·A·sin(φ).

Averaging unit 37 determines the (geometric) average of filtered signals S′ and C′:
X=√(S′²+C′²)=√(¼·A²·cos²(φ)+¼·A²·sin²(φ))=½·A,
which is clearly independent of both ω and φ. If we then use a scaling unit 38 which multiplies the signal X by 2, the resulting signal Y is equal to A:
Y=2·X=2·½·A=A.

In other words, the output Y of the detector 3 is equal to the amplitude of the tonal (sinusoidal) audio input signal. However, if the audio input signal V′ᵢₙ is not sinusoidal but has a noise-like character, the signal X and hence the signal Y will have a value of approximately zero since the average of the product of a sine signal (or cosine signal) and a noise signal will be approximately zero. As a result, the present invention provides a very effective way of detecting tonal signals.

It is noted that in the above example the scaling factor α is set to 2, as this produces a convenient output signal. It is of course possible to use both higher (e.g. 3 or 4.5) and lower (e.g. 0.7 or 1.5) scaling factors, and to omit the scaling unit altogether if a scaling factor of approximately 1 is desired.

It is further noted that although the averaging unit 37 produces a geometric average in the embodiments shown, other averages may also be suitable, such as an arithmetic average.

In the embodiment of FIG. 2 it is assumed that the frequency ω at which the generators 31 and 32 operate is predetermined. This frequency could, for example, be equal to the middle frequency of a frequency band. If the frequency band ranges from, for example, 60 Hz to 100 Hz, a predetermined frequency of approximately 80 Hz would be appropriate. However, it is preferred that the frequency of the generators 31 and 32 is variable and, more in particular, depends on the audio signal.

In the embodiment of FIG. 3, therefore, the detector 3 is further provided with a frequency tracker (“FT”) 39 which receives the audio input signal V′ᵢₙ and determines its (preferably dominant) frequency. This frequency ω is then fed to the generators 31 and 32. As the frequency tracker continuously monitors the input signal, the frequency ω of the generators is continuously adjusted, thus leading to an improved detection of tonal signal components.

A frequency tracker may use a well-known “phase-locked loop” or other techniques to track the frequency. Reference is made to the book “The estimation and tracking of frequencies” by G. Quinn and E. J. Hannan, Cambridge University Press, 2001.

In the embodiment of the device of the present invention shown in FIG. 4 a frequency tracker 39 not only provides the frequency w to the generators 31 and 32 but also to the harmonics generator (“HG”) 2. In this embodiment, therefore, the frequency ω instead of the audio input signal V′ᵢₙ is fed to the harmonics generator 39. Apart from that, the embodiment of FIG. 4 is substantially equal to the combination of the detector of FIG. 3 and the device of FIG. 1.

A preferred embodiment of the device 1 of the present invention is schematically shown in FIG. 5. In this embodiment, the device 1 comprises, in addition to a harmonics generator 2, a detector 3 and a multiplier 4, also a first filter 8, a second filter 9, and an addition circuit 7. The first filter 8 serves to select a frequency band on which the device 1 works, that is, the frequency band which is subjected to enhancement. It will be understood that the first filter 8 is a band-pass filter or a low-pass filter, for example having a pass band ranging from 20 Hz to 200 Hz. The second filter 9 serves to feed those parts of the audio input signal which are not enhanced to the output, via the adder 7. It will be clear that the adder 7 serves to combine the enhanced audio signals with the non-enhanced audio signals so as to produce a combined audio output signal.

The function of the second filter 9 may vary, depending on the particular embodiment of the device 1 and, in particular, of the harmonics generator or equivalent enhancement means 2. If the harmonics generator 2 is arranged for producing sub-harmonics, the second filter 9 preferably is an all-pass filter or delay which serves to compensate for any delays in the first filter 8 and the harmonics generator 2. If the harmonics generator 2 is arranged for generating higher harmonics, the second filter 9 preferably is a high-pass filter which serves to pass those frequencies of which no harmonics are produced.

Although in FIG. 5 only one set of filters and one enhancement unit 2 is shown, it will be understood that many such circuits could be arranged in parallel, each first filter 8 preferably being designed to pass another frequency range. In this way, several frequency ranges can be enhanced independently.

The present invention is based upon the insight that audio signal enhancements such as harmonics or sub-harmonics of parts of the audio signal are only desired when tonal audio signals are being produced. The present invention benefits from the further insight that tonal signals can be detected by multiplication, filtering and averaging, using auxiliary signals having approximately the same frequency as the tonal signal to be detected.

It is noted that any terms used in this document should not be construed so as to limit the scope of the present invention. In particular, the words “comprise(s)” and “comprising” are not meant to exclude any elements not specifically stated. Single (circuit) elements may be substituted with multiple (circuit) elements or with their equivalents.

It will be understood by those skilled in the art that the present invention is not limited to the embodiments illustrated above and that many modifications and additions may be made without departing from the scope of the invention as defined in the appending claims.

1. A method of enhancing an audio signal, the method comprising the steps of:
detecting tonal signal components in a frequency range of the audio signal,
producing enhancement signals, and
adjusting the level of the enhancement signals in dependence of any detected tonal signal components in said frequency range.

2. The method according to claim 1, wherein the enhancement signals are harmonics or sub-harmonics of part of the audio signal.

3. The method according to claim 1, wherein the frequency range comprises bass frequencies.

4. The method according to, wherein the step of detecting tonal frequency components comprises the sub-steps of:
generating a sine signal and a cosine signal,
multiplying both the sine signal and the cosine signal by the audio signal,
filtering the respective multiplied signals, and
determining an average of the low pass filtered signals so as to produce a detection signal.

5. The method according to claim 4, wherein the sine and cosine signals both have a frequency which is substantially equal to a dominant frequency of the frequency range.

6. A device (1) for enhancing an audio signal, the device comprising:
detector means (3) for detecting tonal signal components in a frequency range of the audio signal,
enhancement means (2) for producing enhancement signals, and
adjustment means (4) for adjusting the level of the enhancement signals in dependence of any detected tonal signal components in said frequency range.

7. The device according to claim 6, wherein the enhancement signals are harmonics or sub-harmonics of part of the audio signal.

8. The device according to claim 6, wherein the frequency range comprises bass frequencies.

9. The device according to claim 6, wherein the detector means (3) comprise:
generator means (31, 32) for generating a sine signal and a cosine signal,
multiplication means (33, 34) for multiplying the audio signal by the sine signal and the cosine signal respectively,
filter means (35, 36) for filtering the multiplied sine signal and cosine signal respectively, and
averaging means (37) for determining an average of the filtered signals so as to produce a detector signal.

10. The device according to claim 9, further comprising scaling means (38) for scaling the detector signal.

11. The device according to claim 9, further comprising frequency tracking means (39) for tracking the frequency in the frequency range and controlling the generator means (31, 32).

12. The device according to claim 6, further comprising a first filter (8) for filtering the audio input signal prior to enhancement, a second filter (9) for passing signals not passed by the first filter, and adding means (7) for adding the enhancement signals and the signals passed by the second filter (9).

13. A tonal signal detector (3) comprising:
generator means (31, 32) for generating a sine signal and a cosine signal,
multiplication means (33, 34) for multiplying the audio signal by the sine signal and the cosine signal respectively,
filter means (35, 36) for filtering the multiplied sine signal and cosine signal respectively, and
averaging means (37) for determining an average of the filtered signals so as to produce a detector signal.

14. The detector according to claim 13, further comprising scaling means (38) for scaling the detector signal.

15. The detector according to claim 13, further comprising frequency tracking means (39) for tracking the frequency in the frequency range and controlling the generator means (31, 32).

16. An audio system, comprising a device (1) according to claim 6.
